(19) United States
(12) Patent Application Publication
(10) Pub. No.: US 2012/0291840 A1
(43) Pub. Date: Nov. 22, 2012

(54) PATTERNED TEXTURED GLASS COMPATIBLE WITH LASER SCRIBING

(76) Inventors: Glenn Eric Kohnke, Corning, NY (US); Jia Liu, Painted Post, NY (US); Sasha Marjanovic, Painted Post, NY (US)

(21) Appl. No.: 13/456,799

(22) Filed: Apr. 26, 2012

Related U.S. Application Data
(60) Provisional application No. 61/487,386, filed on May 18, 2011.

(51) Int. Cl. H01L 31/042; H01L 31/18; B32B 33/00

(52) U.S. Cl. 136/244; 428/141; 438/73; 257/E31.11

(57) ABSTRACT

Methods of isolating photovoltaic cells in a module by providing a textured glass substrate with a pattern of textured areas and a pattern of non-textured areas; forming a plurality of photovoltaic cells on the glass substrate; and isolating each of the cells from each adjacent cell to form the module. Glass substrates have a surface with a pattern of textured areas; and a pattern of non-textured areas, wherein the non-textured areas are in the form of strips having an average width of from 10 microns to 500 microns. Articles have a glass substrate having a surface comprising a pattern of textured areas and a pattern of non-textured areas; and a plurality of isolated photovoltaic cells formed on the glass substrate.

This application claims the benefit of priority under 35 U.S.C. §119 of U.S. Provisional Application Ser. No. 61/487,386 filed on May 18, 2011 the content of which is relied upon and incorporated herein by reference in its entirety.

### BACKGROUND

1. Field

Embodiments relate generally to patterned textured glass and more particularly to patterned textured glass compatible with laser scribing useful for, for example, photovoltaic devices.

2. Technical Background

In a superstrate configuration, Si-tandem thin-film photovoltaic solar cells are fabricated by coating a flat glass substrate with a transparent conductive oxide (TCO) followed by amorphous-Si (a-Si) and microcrystalline-Si (uc-Si) p-i-n structures. The backside contact may be metal only or another TCO layer or a combination of TCO and metal. Light is incident on the glass side and then propagates through the front-contact TCO into the Si layers of the solar cell. There is also an alternative configuration known as a substrate configuration where a metallic back reflector is generally used and deposited first on the substrate followed by the silicon layers and a top TCO contact. The remainder of the description will focus on the superstrate configuration. The term “substrate” will refer to glass used in the superstrate configuration.

For the solar cell to operate, it is necessary to make contact to both the front and back contact layers. In addition, a region of the cell must be electrically isolated from the remainder of the module to limit the maximum path of carrier transport prior to collection. The electrically isolated regions are subsequently wired in series with one another. In a full-panel sized photovoltaic module, the cell area is typically 1 cm wide by the height of the panel which is on the order of 1.3 to 1.4 m. To delineate the cells and enable a series connection between adjacent cells, a three-step laser scribing process is typically used.

Since laser scribing enables low cost fabrication of thin-film solar cells, it is highly desirable to have a solution for laser-scribing on textured, for example, microtextured substrates.

### SUMMARY

There is no known prior technology for solving the problem of laser scribing of solar cells on textured substrates since the problem did not exist. There are alternative manufacturing methods such as photolithography or screen printing followed by etching or lift-off processes to define the required cell patterns during the fabrication process. That would require the addition of significant numbers of process steps and add patterning steps between thin film deposition processes. Depending on the number of layers for which this would have to be done, it could very well offset any cost benefit of increased cell efficiency provided by the microtextured substrate.

One embodiment is a method of isolating photovoltaic cells in a module, the method comprises:
providing a textured glass substrate comprising a pattern of textured areas and a pattern of non-textured areas;
forming a plurality of photovoltaic cells on the glass substrate; and
isolating each of the cells from each adjacent cell to form the module.

Another embodiment is an article comprising a glass substrate having a surface comprising a pattern of textured areas and a pattern of non-textured areas; and a plurality of isolated photovoltaic cells formed on the glass substrate.

Another embodiment is a photovoltaic module comprising a glass substrate having a surface comprising a pattern of textured areas and a pattern of non-textured areas; and a plurality of isolated photovoltaic cells formed on the glass substrate.

Another embodiment is a glass substrate having a surface comprising a pattern of textured areas; and a pattern of non-textured areas, wherein the non-textured areas are in the form of strips having an average width of from 10 microns to 500.

Additional features and advantages of the invention will be set forth in the detailed description which follows, and in part will be readily apparent to those skilled in the art from the description or recognized by practicing the invention as described in the written description and claims hereof, as well as the appended drawings.

It is to be understood that both the foregoing general description and the following detailed description are merely exemplary of the invention, and are intended to provide an overview or framework for understanding the nature and character of the invention as it is claimed.

The accompanying drawings are included to provide a further understanding of the invention, and are incorporated in and constitute a part of this specification. The drawings illustrate one or more embodiment(s) of the invention and together with the description serve to explain the principles and operation of the invention.

### BRIEF DESCRIPTION OF THE DRAWINGS

The invention can be understood from the following detailed description either alone or together with the accompanying drawing figures.

FIG. 1 shows patterning steps for cell isolation and series connection in a Si-tandem thin-film solar cell. Patterns #2 and #3 are performed using laser illumination through the glass substrate.

FIG. 2 shows a schematic illustration of a patterned microtextured substrate.

### DETAILED DESCRIPTION

Reference will now be made in detail to various embodiments of the invention.

As used herein, the term “substrate” can be used to describe either a substrate or a superstrate depending on the configuration of the photovoltaic cell. For example, the substrate is a superstrate, if when assembled into a photovoltaic cell, it is on the light incident side of a photovoltaic cell. The superstrate can provide protection for the photovoltaic materials from impact and environmental degradation while allowing transmission of the appropriate wavelengths of the solar spectrum. Further, multiple photovoltaic cells can be arranged into a photovoltaic module. Photovoltaic device can describe either a cell, a module, or both.

As used herein, the term “adjacent” can be defined as being in close proximity. Adjacent structures may or may not be in physical contact with each other. Adjacent structures can have other layers and/or structures disposed between them.

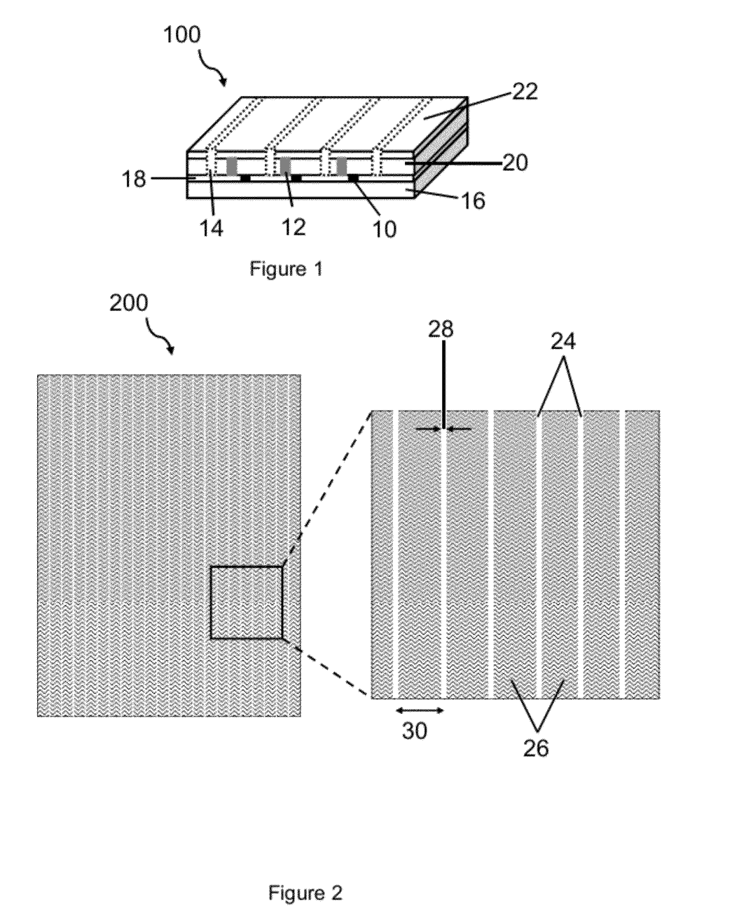

FIG. 1 illustrates the three laser scribing patterns that are needed for cell isolation in a photovoltaic module 100. Pattern #1 (front contact scribe) 10 is obtained, for example, with a 1064 nm laser from the cell side. Patterns #2 and #3, 12 and 14, respectively, are typically made using a 532 nm laser from the glass side. The combined lateral width of the three scribed regions is in the range of 150 to 300 microns. This process is extensively used in the large scale manufacturing of thin-film solar cells. In FIG. 1, the structure of the photovoltaic module stack is glass 16, front TCO 18, photovoltaic functional material 20, and back contact 22.

Initial experiments have found that laser scribing pattern #3, 14 in FIG. 1, is difficult when done on a textured glass substrate, for example, a microtextured glass substrate fabricated by lapping and etching. It is not clear whether this is due to distortions of the laser beam by the microtexturing or locally varying stress distributions in the thin-film stack due to the surface irregularities.

One embodiment is a method of isolating photovoltaic cells in a module, the method comprises:
providing a textured glass substrate comprising a pattern of textured areas and a pattern of non-textured areas;
forming a plurality of photovoltaic cells on the glass substrate; and
isolating each of the cells from each adjacent cell to form the module.

Another embodiment is an article comprising a glass substrate having a surface comprising a pattern of textured areas and a pattern of non-textured areas; and a plurality of isolated photovoltaic cells formed on the glass substrate.

Another embodiment is a photovoltaic module comprising a glass substrate having a surface comprising a pattern of textured areas and a pattern of non-textured areas; and a plurality of isolated photovoltaic cells formed on the glass substrate.

Another embodiment is a glass substrate having a surface comprising a pattern of textured areas; and a pattern of non-textured areas, wherein the non-textured areas are in the form of strips having an average width of from 10 microns to 500 microns, for example, from 10 microns to 400 microns, for example, from 50 microns to 300 microns, for example, 75 microns to 300 microns, for example, 100 microns to 300 microns, for example, 125 microns to 300 microns, for example, 150 microns to 300 microns.

In one embodiment, the providing comprises forming the pattern of textured areas and the pattern of non-textured areas. The forming the pattern of textured areas according to some embodiments comprises providing a glass substrate; and texturing a surface of the glass substrate using a process selected from a chemical process, a mechanical process, or a combination thereof. The forming the pattern of textured areas can comprise sandblasting the glass substrate, etching the glass substrate, grinding the glass substrate, lapping the glass substrate, depositing particles on the glass substrate, or a combination thereof.

In one embodiment, the forming the pattern of non-textured areas comprises providing a glass substrate; and masking areas of the glass substrate to prevent texturing in the masked areas. The masking can comprise applying a polymer, a tape, a photoresist, a screen printed material, or a combination thereof.

In one embodiment, the forming the pattern of non-textured areas comprises providing a glass substrate; texturing the glass substrate; and removing the texture from areas of the glass substrate. The removing can comprise lapping areas of the textured glass substrate, etching areas of the textured glass substrate, grinding areas of the textured glass substrate, heating areas of the textured glass substrate, or a combination thereof.

The article or the glass substrate according to one embodiment has a majority of the surface comprising the textured areas and a minority of the surface comprising the non-textured areas. The textured areas and non-textured areas can alternate. The non-textured areas in one embodiment are in the form of strips having an average width of from 150 microns to 300 microns. The non-textured areas can be in the form of strips, wherein the strips have an average width capable of fitting three laser scribes. In one embodiment, the textured areas are in the form of strips having an average width of from 0.5 cm to 2 cm.

The invention is a patterned glass where the majority of the glass surface contains a microtexture and small areas in the form of strips are left as a flat glass. The small flat areas have a width of 10 microns to 500 microns, for example, from 10 microns to 400 microns, for example, from 50 microns to 300 microns, for example, 75 microns to 300 microns, for example, 100 microns to 300 microns, for example, 125 microns to 300 microns, for example, 150 microns to 300 microns, which is wide enough to fit all three laser scribes. The invention is also the article made by several methods of creating a patterned microtextured glass surface. The methods include masking during sandblasting or polymer etch mask formation, patterned surface functionalization prior to particle deposition, patterning an adhesive layer prior to particle deposition, localized grinding and/or polishing, etc.

One embodiment of the patterned microtextured glass 200 is schematically illustrated in FIG. 2. The flat glass pattern 24 follows the scribe pattern of a module. The textured glass 26, in one embodiment is located between the flat glass. The module size for Si-Tandem solar cells is currently Gen 5 display glass which includes a range of sizes (1.1×1.3 m, 1.0×1.4 m, and 1.1×1.4 m). A typical cell width 30 of a module is 1 cm which runs the entire length of the module. The scribe area or flat glass area 28 is in the range of from 150 microns to 300 microns, according to one embodiment.

The method of patterning can be generally tied to the method of forming the texture on the glass. A patterning technique that is applicable to one method of texturing may not be applicable to another. These include lapping and etching, sandblasting and etching, polymer masking and etching, self-assembling a particle monolayer and heating, adhesive attachment of a particle monolayer and heating, deposition of particles in or on sol-gel followed by heating, and in-line deposition of high-temperature particles on a softened substrate or low-temperature particles on a heated substrate.

One example of a self-assembly method comprises functionalizing inorganic particles using a silane, spreading the functionalized particles on the surface of water (or an aqueous solution) for form a monolayer, and moving a substrate through the particle monolayer to deposit the particle monolayer on one or both surfaces of the substrate. The particle monolayer is subsequently attached to the substrate by heating, which comprises partially slumping the particles on the substrate (for low-melting particles), or softening the substrate and partially sinking the particles into the substrate (for high-melting particles), or by a combination thereof.

One example of an adhesive attachment method comprises depositing a layer of adhesive on a substrate and then depositing a particle monolayer on top of the adhesive layer (by, for example, pressing the substrate with the adhesive layer onto a powder of the particles, or spraying a powder of the particles of the substrate with the adhesive layer, followed by brushing off excess particles). The particle monolayer is subsequently attached to the substrate by heating, which comprises partially slumping the particles on the substrate (for low-melting particles), or softening the substrate and partially sinking the particles into the substrate (for high-melting particles), or by a combination thereof. The organic components in the adhesive are burned off during the heating process.

Potential patterning methods applicable to each approach are detailed in the following:

1. Lapping and Etching
Patterning is done after texturing (see #9)

2. Sandblasting and Etching
Pattern the surface with a mask prior to sandblasting
   Mask materials: polymer, tape
   Mask formation methods: screen printing, photolithography, tape application
Place a pre-made and reusable mask with desired pattern on the substrate prior to sandblasting

3. Polymer Masking and Etching
Same as Sandblasting and Etching

4. Self-assembling a particle monolayer and heating
a. Pattern substrate surface with hydrophilic/hydrophobic regions prior to self-assembling so that particles deposit in hydrophilic regions but not in hydrophobic regions or vice versa
b. Pattern substrate surface with chemically active/inert regions prior to self-assembling and selectively remove particles from inert regions
c. Self-assemble particles onto a patterned polymer stamp pad for transfer to the substrate
d. Coating with photoresist after self-assembling followed by patterned UV exposure and rinsing
e. Localized removal of particles in laser scribe area after self-assembling
f. Pattern substrate with a masking material (e.g. polymer, tape) prior to self-assembling and remove masking material with particles after self-assembling
g. Self-assemble by placing a pre-made and reusable mask with desired pattern on the substrate so that particles are deposited in pattern

5. Adhesive attachment of a particle monolayer and heating
a. Pattern the adhesive layer prior to particle deposition by using a patterned roller during a roller-based adhesive deposition process
b. Pattern the adhesive layer prior to particle deposition by using localized removal of adhesive prior to particle deposition
c. Pattern the adhesive layer prior to particle deposition by using screen printing
d. Without patterning the adhesive layer, place a pre-made and reusable mask with desired pattern on the substrate prior to particle deposition so that particles are deposited in pattern

6. Deposition of particles in or on sol-gel followed by heating
Pattern sol-gel by e.g., screen printing

7. In-line deposition of high-temperature particles on a softened substrate
Patterning has to be done after texturing (see #9)

8. In-line deposition of low-temperature particles on a heated substrate
Patterning has to be done after texturing (see #9)

9. Generally applicable to all approaches
a. Localized grind or polish within the laser scribe region after forming the texture
b. Localized glass heating (e.g., laser heating) to smooth texture in the laser scribe region after forming the texture

The glass substrate can be of any composition or combinations of compositions. In some embodiments, the glass substrate is a specialty glass, a thin specialty glass, a strengthened glass, a sodalime glass, a borosilicate glass, an aluminosilicate glass, a aluminoborosilicate glass, an alkali-free glass, or combinations thereof. The photovoltaic module can comprise one or more glass substrates.

In one embodiment, the glass sheet is transparent. In one embodiment, the glass sheet as the substrate and/or superstrate is transparent.

In some embodiments, the glass substrate is substantially planar having two opposing substantially parallel surfaces. In one embodiment, the glass is substantially planar, for example, the textured glass is planar on the macro scale with only the texture providing micro variances to the planarity.

According to some embodiments, the glass substrate has a thickness of 4.0 mm or less, for example, 3.5 mm or less, for example, 3.2 mm or less, for example, 3.0 mm or less, for example, 2.5 mm or less, for example, 2.0 mm or less, for example, 1.9 mm or less, for example, 1.8 mm or less, for example, 1.5 mm or less, for example, 1.1 mm or less, for example, 0.5 mm to 2.0 mm, for example, 0.5 mm to 1.1 mm, for example, 0.7 mm to 1.1 mm. Although these are exemplary thicknesses, the glass substrate can have a thickness of any numerical value including decimal places in the range of from 0.1 mm up to and including 4.0 mm.

It will be apparent to those skilled in the art that various modifications and variations can be made to the present invention without departing from the spirit or scope of the invention. Thus, it is intended that the present invention cover the modifications and variations of this invention provided they come within the scope of the appended claims and their equivalents.

What is claimed is:

1. A method of isolating photovoltaic cells in a module, the method comprising:
providing a textured glass substrate comprising a pattern of textured areas and a pattern of non-textured areas;
forming a plurality of photovoltaic cells on the glass substrate; and
isolating each of the cells from each adjacent cell to form the module.

2. The method according to claim 1, wherein the providing comprises forming the pattern of textured areas and the pattern of non-textured areas.

3. The method according to claim 2, wherein the forming the pattern of textured areas comprises providing a glass substrate; and texturing a surface of the glass substrate using a process selected from a chemical process, a mechanical process, or a combination thereof.

4. The method according to claim 3, wherein the forming the pattern of textured areas comprises sandblasting the glass substrate, etching the glass substrate, grinding the glass substrate, lapping the glass substrate, depositing particles on the glass substrate, or a combination thereof.

5. The method according to claim 2, wherein the forming the pattern of non-textured areas comprises providing a glass substrate; and masking areas of the glass substrate to prevent texturing in the masked areas.

6. The method according to claim 5, wherein the masking comprises applying a polymer, a tape, a photoresist, a screen printed material, or a combination thereof.

7. The method according to claim 2, wherein the forming the pattern of non-textured areas comprises providing a glass substrate; texturing the glass substrate; and removing the texture from areas of the glass substrate.

8. The method according to claim 7, wherein the removing comprises lapping areas of the textured glass substrate, etching areas of the textured glass substrate, grinding areas of the textured glass substrate, heating areas of the textured glass substrate, or a combination thereof.

9. An article comprising a glass substrate having a surface comprising a pattern of textured areas and a pattern of non-textured areas; and a plurality of isolated photovoltaic cells formed on the glass substrate.

10. The article according to claim 9, wherein a majority of the surface comprises the textured areas and a minority of the surface comprises the non-textured areas.

11. The article according to claim 9, wherein the textured areas and non-textured areas alternate.

12. The article according to claim 9, wherein the non-textured areas are in the form of strips having an average width of from 10 microns to 500 microns.

13. The article according to claim 9, wherein the non-textured areas are in the form of strips, wherein the strips have an average width capable of fitting three laser scribes.

14. A photovoltaic module comprising a glass substrate having a surface comprising a pattern of textured areas and a pattern of non-textured areas; and a plurality of isolated photovoltaic cells formed on the glass substrate.

15. A glass substrate having a surface comprising a pattern of textured areas; and a pattern of non-textured areas, wherein the non-textured areas are in the form of strips having an average width of from 10 microns to 500 microns.

16. The glass substrate according to claim 15, wherein the textured areas are in the form of strips having an average width of from 0.5 cm to 2 cm.

17. The glass substrate according to claim 15, wherein a majority of the surface comprises the textured areas and a minority of the surface comprises the non-textured areas.

18. The glass substrate according to claim 15, wherein the textured areas and non-textured areas alternate.

19. The glass substrate according to claim 15, wherein the glass substrate is substantially planar having two opposing substantially parallel surfaces.

20. The glass substrate according to claim 15, wherein the glass substrate is a specialty glass, a thin specialty glass, a strengthened glass, a sodalime glass, a borosilicate glass, an aluminosilicate glass, a aluminoborosilicate glass, an alkali-free glass, or combinations thereof.
